(19) United States
(12) Patent Application Publication
(10) Pub. No.: US 2016/0284632 A1
(43) Pub. Date: Sep. 29, 2016

(54) ELECTRONIC COMPONENT PACKAGE

(71) Applicant: AISIN SEIKI KABUSHIKI KAISHA, Kariya-shi, Aichi (JP)

(72) Inventors: Minoru SHINOHARA, Anjo-shi (JP); Naoki Nakamura, Okazaki-shi (JP)

(73) Assignee: AISIN SEIKI KABUSHIKI KAISHA, Kariya-shi, Aichi (JP)

(21) Appl. No.: 15/034,633

(22) PCT Filed: Oct. 20, 2014
(86) PCT No.: PCT/JP2014/077810

§ 371 Date: May 5, 2016

(30) Foreign Application Priority Data
Nov. 8, 2013 (JP) 2013-232124

(51) Int. Cl. H01L 23/495; H01L 25/065; H01L 23/00; H01L 23/31

(52) U.S. Cl. CPC H01L 23/49541; H01L 23/3121; H01L 23/49555; H01L 25/0655; H01L 24/06; H01L 23/49575

(57) ABSTRACT

Provided is a rational arrangement of an electronic component package that tightly keeps a connecting state of a lead member to a conductive pad of a substrate. The electronic component package includes a substrate having a conductive pad and mounting an electronic component, a lead member electrically conducted to the conductive pad, and a molded portion in which the above members are embedded. The lead member includes an inner conductor having bifurcated end portions and a unitary portion formed integral therewith. The inner conductor and a part of the unitary portion which are embedded in the molded portion are curved in protrusive or sunken manner relative to an imaginary plane extending along the surface of the substrate.

### TECHNICAL FIELD

The present disclosure relates to an electronic component package. More particularly, the disclosure relates to a package including a lead member electrically conducted to an electronic component supported on a substrate via a conductive pad of the substrate, with a base end portion of the lead member and the electronic component being embedded in a molded portion.

### BACKGROUND ART

As an example of the electronic component package configured as described above, Patent Document 1 discloses a semiconductor device configured such that a wide conductive pad (a wide land portion in the document) is formed for an integrated circuit board and there is provided a lead terminal having a wide common fixing piece to be soldered to the conductive pad, with the above components being contained in a sealed manner within a resin package.

According to this Patent Document 1, a conductive pad wider than a common fixing piece is formed on the substrate and as these are bonded to each other, by solder, there is provided improved fixing strength. Further, resistance against slipping from the package is improved via the shape of the lead terminal.

Patent Document 2 discloses an arrangement including a substrate, a frame body surrounding the substrate and a lead terminal supported to the substrate, an inner end portion of the lead terminal being bonded via a bonding member to a wiring conductor formed on the inner side of the frame body.

This Patent Document 2 addresses to a problem of smallness of bonding area and corresponding reduction in the bonding performance between the lead terminal and the wiring conductor resulting from forming the package compact. To solve this problem, branching portions are formed in the wiring conductor and the lead terminal, so that for bonding to a wire member, the bonding member is caused to be present relative not only to a lower face of the lead member, but also to the inner face side of the branching portions.

### CITATION LIST

### Patent Literature

Patent Document 1: Japanese Unexamined Patent Application Publication No. 8-130282

Patent Document 2: Japanese Unexamined Patent Application Publication No. 2012-114337

### SUMMARY OF INVENTION

### Technical Problem

In the case of the package having a substrate and a lead member molded together with resin, when heat is generated in the package with supply of electric power thereto, a stress will be developed due to thermal expansion of the molded portion and/or thermal expansion of the lead member. And, this stress may sometimes be applied in a direction that tends to separate the lead member from the conductive pad.

In particular, in case there is a difference of expansion coefficient between the lead member and the mold, in the event of such heat generation in the package, a strong stress will be applied in the direction tending to separate the lead member from the conductive pad, whereby the lead member may be accidentally detached from the conductive pad. Thus, improvement is desired in this regard.

In addressing to such problem as above, for realization of stronger bonding of the inner end side of the lead member to the conductive pad portion of the substrate, increasing the contact area relative to the pad as shown in Patent Document 1 or Patent Document 2 will be effective. However, with simple increase of the contact area between the pad portion and the lead member, this would lead to physical enlargement of the pad portion and the lead member, thus inhibiting compactization of the package.

The object of the present invention is to provide a rational arrangement of an electronic component package that tightly keeps a connecting state of a lead member to a conductive pad of a substrate.

### Solution to Problem

According to a characterizing feature of the present invention, an electronic component package comprises:

a substrate having a conductive pad and mounting an electronic component;

a lead member having bifurcated end portions to be electrically conducted to the conductive pad; and

a molded portion in which the substrate together with the bifurcated end portions and a part of a unitary portion continuous from the bifurcated end portions of the lead portion are embedded therein;

wherein the portions of the lead member embedded in the molded portion are curved in protrusive or sunken manner relative to an imaginary plane extending parallel with a surface of the substrate.

With the above-described configuration, the bifurcated end portions of the lead member are connected to the conductive pad. Therefore, when the bifurcated end portions are bonded to the conductive pad with soldering, for instance, bonding over a large area at two points is made possible. With the solder bonding arrangement described above, excess solder will be present in the area surrounding the outer circumferences of the bifurcated end portions at the two points contacting the conductive pad, so that the contact area of the solder can be increased, thus realizing increase of the bonding force. Further, the portions of the lead member embedded in the molded portion are curved in protrusive or sunken manner relative to an imaginary plane extending parallel with a surface of the substrate. Therefore, even when heat is generated in the package, it is still possible to cause the stress to be applied in an offsetting direction relative to the lead member, so that it is possible to reduce the force effective in the direction tending to detach the lead member from the conductive pad. Consequently, there has been realized an electronic component package that tightly keeps a connecting state of a lead member to a conductive pad of a substrate.

In the present invention, the unitary portion can have a width smaller than a width of the bifurcated end portions.

With the above-described arrangement, when a stress is applied to the lead member in the direction of detaching it, the bifurcated end portions having a width greater than the width of the unitary portion will come into firm contact with the resin mold, thus preventing displacement in the detaching direction.

In the present invention, preferably, the bifurcated end portions are designed to separate end portions of an inner conductor formed on an inner end side of the lead member from each other with a slit portion therebetween, the slit portion having a greater width than the width of the unitary portion.

With the above-described arrangement, since the width of the unitary portion is smaller than the width of the slit portion, when a connecting portion between the inner conductor and the unitary portion is subjected to a force in a direction of twisting this portion on, a deformation will readily occur between the inner conductor and the unitary portion. As a result, phenomenon of a strong force acting between the inner conductor and the conductive pad is suppressed, so that the connected state between the inner conductor and the conductive pad can be maintained favorably.

In the present invention, preferably, a widthwise center of the slit portion and a widthwise center of the unitary portion are disposed on a common center axis.

With the above-described arrangement, the bifurcated end portions of the inner conductor are disposed at positions symmetric to each other across the center axis. Therefore, even when a stress is applied to the unitary portion for instance, equal loads will be applied to the pair of inner end portions, so that inconvenience of load being applied only to one of them in a concentrated manner can be avoided and the bonded state of the lead member can be maintained.

In the present invention, preferably, a pair of contact pieces are formed at inner ends of the inner conductor and set with such a contact angle that causes the pair of contact pieces to contact with a surface of the conductive pad under a posture with inner end side of the pair of contact pieces raised.

With the above-described arrangement, when the pair of contact pieces at the inner ends of the inner conductor are caused to contact with the surface of the pad, inner end sides of the contact pieces are raised. Therefore, when the contact to the pad occurs via solder, an amount of molten solder will flow from the raised portion into the gap between the contact pieces and the pad, thus allowing the contact between the pad and the contact pieces to occur over a large face.

In the present invention, preferably, the lead member includes an inner conductor embedded in the molded portion, an intermediate conductor extending continuously from the inner conductor and embedded in the molded portion, and an outer conductor extending continuously from the intermediate conductor: and

the bifurcated end portions are formed in the inner conductor and the unitary portion is formed in the intermediate conductor and the outer conductor.

With the above-described arrangement, the bifurcated end portions of the inner conductor connected to the conductive pad and the unitary portion of the intermediate conductor connected to the inner conductor are embedded together in the molded portion. So, the contact state between the inner conductor and the conductive pad can be maintained favorably.

In the present invention, preferably, the inner conductor includes a wide portion and a pair of extension portions extending from the wide portion at positions across a slit portion that separates the end portions of the inner conductor from each other and

at extension ends of the pair of extension portions, there are formed connecting pieces connected to the conductive pad.

With the above-described arrangement, since the connecting pieces of the pair of extension portions connected to the conductive pad are supported by the wide portion, the contact state between the inner conductor and the conductive pad can be maintained in an even more reliable manner.

In the present invention, preferably, in an intra-mold conductor area where the lead member is molded, an area where the inner conductor is present is defined as a first area and an area where the intermediate conductor is present is defined as a second area;

in the first area, a first level difference is set between the contact pieces and a portion of the inner conductor parallel with the imaginary plane, and

in the second area, a second level difference is set between a portion of the intermediate conductor extending continuously from the inner conductor and a portion of the intermediate conductor extending continuously from the outer conductor.

With the above-described arrangement, when the contact state between the conductive pad and the connecting pieces is maintained, the first level difference and the second level difference are formed inside the intra-mold conductor area. Namely, as the inner conductor and the intermediate conductor embedded in the molded portion are bent in a protruding manner or sunken manner, even when heat is generated in the package, a stress will be applied to the lead member in the offsetting direction. Therefore, the force effective in the direction of detaching the connecting pieces of the lead member from the conductive pad can be reduced advantageously.

In the present invention, preferably, the intermediate conductor has a width which is smaller than a width of the pair of extension portions and which also is greater than the width of the slit portion.

With the above-described arrangement, when an external force is applied in the direction tending to detach the lead member from the conductive pad, the extension portions wider than the intermediate conductor come into firm contact with the molded portion, thereby to strongly prevent displacement in the departing direction. Further, since the width of the intermediate conductor is set greater than the width of the slit portion, even if an external force is applied to the lead member in the twisting direction, displacement thereof in the twisting direction can be prevented by the intermediate conductor. As a result, when the lead member is set relative to the substrate for instance, it is possible to avoid inconvenience of the lead member being deformed in the twisting direction.

In the present invention, preferably, a plurality of the lead members are provided to extend along one direction; and

a plurality of lead tie bars for connecting adjacent lead members are arranged in a non-linear manner under a posture perpendicular to the extending direction.

With the above-described arrangement, since a plurality of lead tie bars are arranged in a non-linear manner, in the event of thermal expansions occurring in the lead tie bars at the time of molding, the stresses applied to the respective lead members will be diffused. Thus, adverse influence from thermal expansion of lead tie bars can be relieved and the positional relationship between the lead members and the conductive pad can be maintained.

### BRIEF DESCRIPTION OF DRAWINGS

FIG. 1 is a section view showing a lead member connected to a substrate,

FIG. 2 is a plane view showing the lead member connected to the substrate,

FIG. 3 is a plane view showing the substrate and a lead frame,

FIG. 4 is a perspective view showing lead members constituting the lead frame and the substrate,

FIG. 5 is a partially cutaway perspective view showing an electronic component package, and

FIG. 6 is a plane view showing a lead to a substrate in a further embodiment (a).

### DESCRIPTION OF EMBODIMENTS

Next, an embodiment of the present invention will be explained with reference to the accompanying drawings.

[Basic Arrangement]

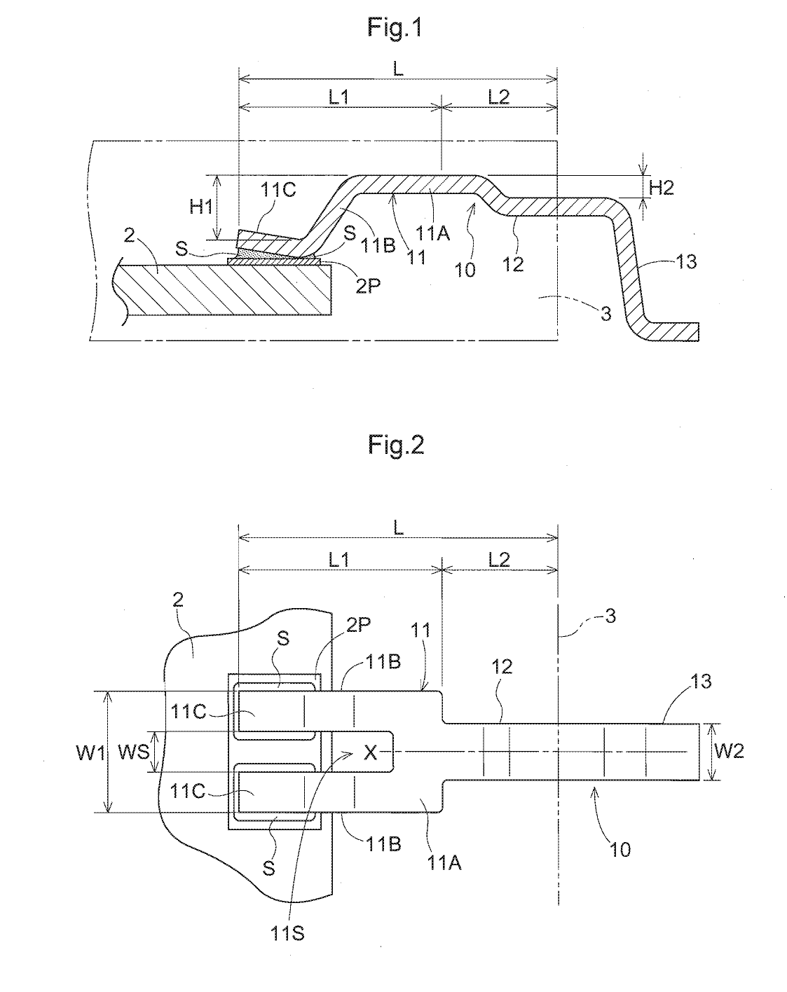

As shown in FIG. 1, FIG. 2 and FIG. 5, an electronic component package is constituted of a substrate 2 mounting/supporting a plurality of electronic components 1, a plurality of lead members 10 connected to a plurality of conductive pads 2P of this substrate 2, and a molded portion 3 formed of resin for embedding the above components.

With the electronic component package of this invention, on the surface of the substrate 2, there is formed a wiring pattern made of conductor, and to this wiring pattern, the electronic components 1 such as semiconductors, resistors, etc. are connected by solder S. And, the conductive pads 2P conducted to these wires are formed on the surface of the substrate 2. And, to these conductive pads 2P, base end portions of the lead members 10 are connected with the solder S (a specific example of brazing).

[Lead Members]

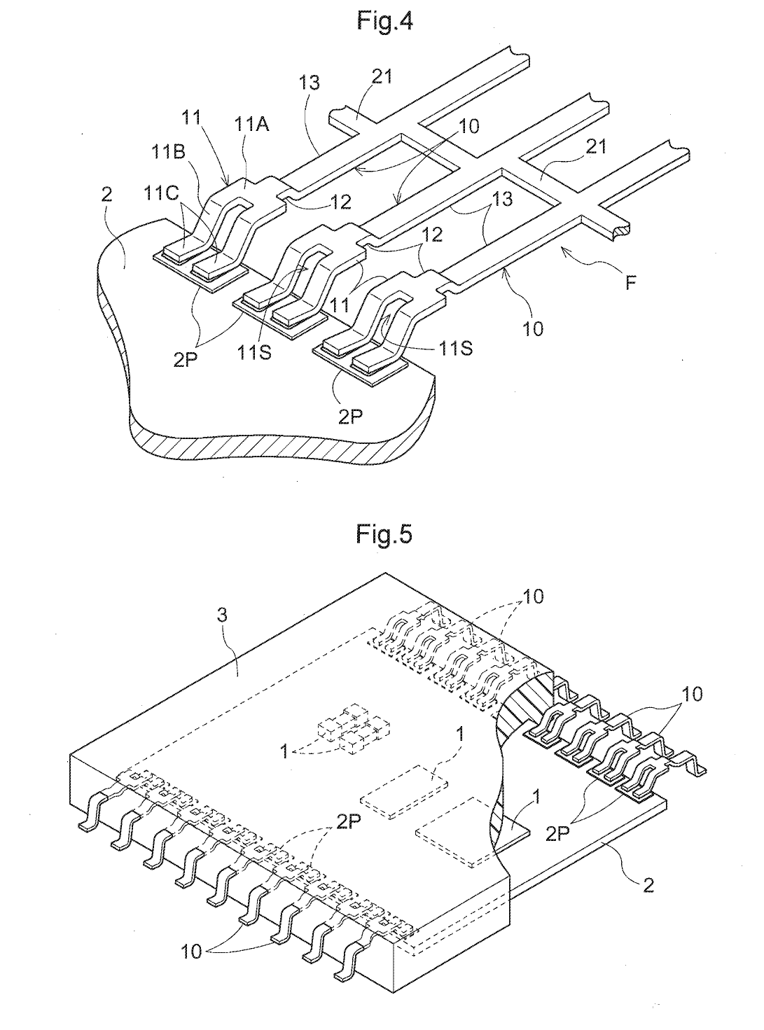

As shown in FIG. 1, FIG. 2 and FIG. 4, each lead member 10 comprises an integrated arrangement consisting of an inner conductor 11 as bifurcated end portions embedded in the molded portion 3, an intermediate conductor 12 as a unitary portion extending continuously therefrom, and an outer conductor 13 as a unitary portion extending continuously therefrom. These portions, i.e. the inner conductor 11, the intermediate conductor 12 and the outer conductor 13 are formed with using a conductive material having a predetermined thickness such as copper, a copper alloy, etc.

The intermediate conductor 12 is embedded inside the molded portion 3, whereas the outer conductor 13 extends continuously from the intermediate conductor 12 and is disposed outside the molded portion 3. With this lead member 10, the inner conductor 11 and the intermediate conductor 12 will be collectively referred to as an “intra-mold conductor area L” embedded in the molded portion 3.

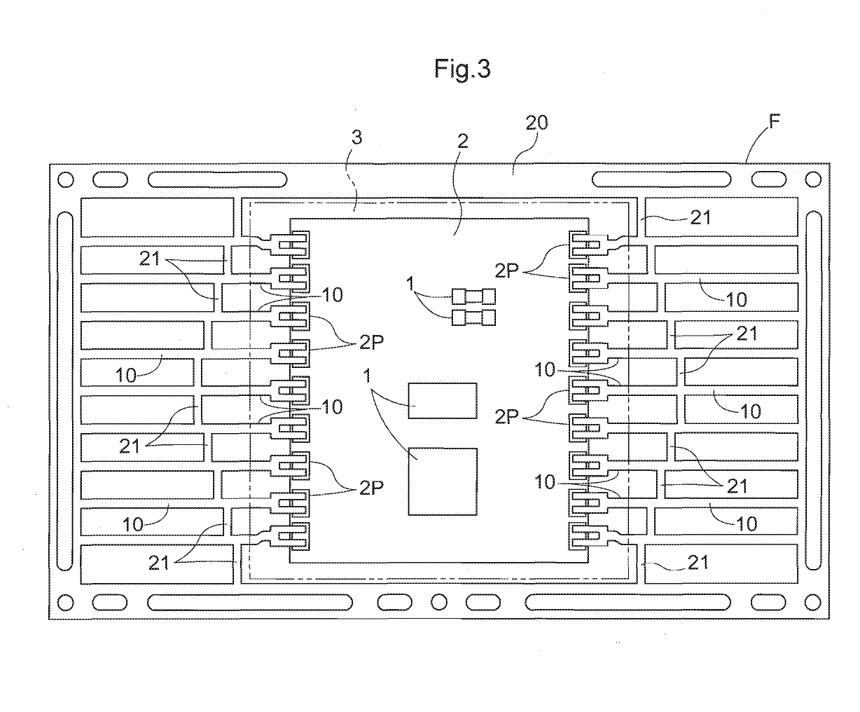

In the process of bonding the lead members 10 to the plurality of conductive pads 2P of the substrate 2, as shown in FIG. 3, there is employed a lead frame F having the plurality of lead members 10 formed integral therewith. The manufacturing process using this lead frame F will be described later herein.

The inner conductor 11 consists essentially of a wide portion 11A having a large width and a pair of extension portions 11B extending at positions across a slit portion 11S therebetween. These paired extension portions 11B are bifurcated and at extension ends (ends of the base end sides) of these extension portions 11B, there are formed connecting pieces 11C connected to the conductive pads 2P.

Assuming an imaginary plane postured along the surface of the substrate 2, the connecting pieces 11C are set with such a contact angle that an inner end side of the inner conductor 11 will contact under a posture slightly raised from the imaginary plane (from the conductive pad 2P). With this, the pair of extension portions 11B form a gap which progressively extends away from the imaginary plane as it extends towards the end side (the left side in FIG. 1). Further, the pair of extension portions 11B of the inner conductor 11 are set with a posture that is raised at a predetermined angle relative to the imaginary plane as it extends towards the outer end side (the side of the outer conductor 13) relative to the positions thereof to be connected to the conductive pad 2P. Moreover, a portion inclusive of an intermediate portion of this extension portion 11B and of the wide portion 11A is formed under a parallel posture along the imaginary plane.

In the intermediate conductor 12, a portion thereof continuous from the wide portion 11A of the inner conductor 11 is formed parallel with the imaginary plane and the area thereof extending continuously from here to the outer end side is formed under a sloped posture extending in a direction approaching the imaginary plane. Furthermore, the portion of this intermediate conductor 12 extending continuously with the outer conductor 13 is formed parallel with the imaginary plane.

To the above intermediate conductor 12, the outer conductor 13 contacts and the outer end portion of this outer conductor 13 will be shaped into a form shown in FIG. 1 after formation of the molded portion 3. Further, a widthwise center of the slit portion 11S and a widthwise center of the intermediate conductor 12 are disposed on a center axis X along the longitudinal direction of the lead member 10, as shown in FIG. 2.

In the intra-mold conductor area L, an area thereof where the inner conductor 11 is present will be referred to as a first area L1, and an area thereof where the intermediate conductor 12 is present will be referred to as a second area L2, respectively. Further, in the inner conductor 11, relative to the connecting pieces 11C, a level difference to the area parallel with the imaginary plane will be referred to as first level difference H1; and in the intermediate conductor 12, a level difference between a portion thereof continuous with the inner conductor 11 and a portion thereof continuous with the outer conductor 13 will be referred to as a second level difference H2, respectively.

As described above, with the above-described setting of the first level difference H1 and the second level difference H2, the intra-mold conductor area L of the lead member 10 is formed in a protruding manner relative to the above-described imaginary plane.

In particular, in the instant embodiment, the intra-mold conductor area L of the lead member 10 is curved in the protruding manner relative to the imaginary plane as described above. Alternatively, the lead member 10 can be bent in a sunken manner for instance. Moreover, in the instant embodiment, the lead member 10 is conducively connected to the conductive pad 2P on the front face of the substrate 2. Alternatively, the lead member 10 can be conductively connected to the conductive pad 2P formed on the back face of the substrate 2. In this case, the lead member 10 constituting the intra-mold conductor area L can be formed in a protruding or sunken manner relative to the imaginary plane.

Further, the lead member 10 can be bent at three or more positions in order to form a plurality of protrusions or recesses in the intra-mold conductor area L, or the lead member 10 can be bent at three or more positions in order to provide combination of protrusions and recesses.

As shown in FIG. 2, in the intra-mold conductor area L, as compared with an extension portion width W1 (corresponding to the width of the wide portion 11A) inclusive of the pair of extension portions 11B, an intermediate portion width W2 of the intermediate conductor 12 is set smaller. Further, the intermediate portion width W2 is set larger than a slit width WS of the slit portion 11S between the pair of extension portions 11B.

[Manufacturing Process of Electronic Component Package]

In manufacturing of this electronic component package, the electronic components 1 will be arranged relative to the substrate 2 and mounted thereon to be conductively connected to the predetermined wires by the solder S. Then, the lead frame F will be arranged such that the connecting pieces 11C of the lead members 10 will come into contact with the surfaces of the conductive pads 2P on the substrate 2 under the above-described mounted state and the conductive pads 2P and the connecting pieces 11C will be connected to each other with the solder S. Then, these members and components will be set inside molding dies and an amount of liquid resin having insulating property and thermoplastic property will be introduced and then solidified, whereby the molded portion 3 will be formed to embed the above members and components therein. After this molding of he molded portion 3, unnecessary portions of the lead frame F (an outer frame 20 and lead tie bars 21) will be removed and then, the outer conductors 13 of the lead members 10 will be bent, whereby the packaging of the electronic components 1 will be completed.

Incidentally, instead of the above-described process, the electronic components 1 may be mounted on the substrate 2 after connection of the connecting pieces 11C of the lead members 10 to the conductive pads 2P of the substrate 2.

As shown in FIG. 3, the lead frame F is an integral assembly formed by pressing of a conductor plate of copper, a copper alloy or the like, having the outer frame 20 having a rectangular shape, the plurality of lead members 10 having ends thereof supported to the outer frame 20 and the plurality of lead tie bars 21 bridging the plurality of lead members 10 to each other. In this lead frame F, the inner conductors 11, the intermediate conductors 12 and the outer conductors 13 of the lead members 10 are formed integral with each other. Further, in each lead member 10 formed in this lead frame F, the shapes of the connecting pieces 11C, the extension portions 11B the intermediate conductor 12, etc. are set by bending works.

Incidentally, in the case of the lead frame F shown in FIG. 3, not all of the lead members 10 are configured such that the inner conductor 11 and the intermediate conductor 12 thereof are aligned on the center axis X. Rather, in the lead members 10 disposed at the outer end positions, the axis of the inner conductor 11 and the axis of the intermediate conductor 12 are disposed under different state.

As shown in the same figure as above, the plurality of lead tie bars 21 provide connection with the lead members 10 assuming a posture perpendicular to the extending direction of the lead members 10. However, the plurality of lead tie bars 21 are not disposed on a same axis, but those of the plurality of lead members 10 disposed on the center side in the disposing direction will be disposed at positions away from the outer edge of the substrate 2 (non-linear arrangement).

For instance, in the case of a plurality of lead tie bars 21 being linearly arranged, thermal expansion will occur in the plurality of lead tie bars 21 due to the heat applied at the time of molding of the molded portion 3, so that a significant force will be applied to the lead members 10. As a result of this effect, the plurality of lead members 10 may sometimes be displaced in the direction of increasing the spacing between adjacent lead members 10, thus applying a force that tends to detach the inner conductor 11 from the conductive pad 2P.

Whereas, in the case of the above-described non-linear layout of the plurality of lead tie bars 21, even when thermal expansion occurs in the lead tie bars 21 at the time of molding, thus applying forces to the respective lead members 10, these forces can be diffused to lessen the effect. Consequently, the positional relationship between the lead member 10 and the conductive pad 2P can be maintained. Further, the above-described non-linear arrangement of the plurality of lead he bars 21 realizes also reduction of influence of internal stress after the molding of the molded portion 3.

In particular, the arrangement of the plurality of lead tie bars 21 is not limited to the arrangement shown in the same figure wherein they are arranged in arcuate regions or chevron-shaped regions. Instead, for instance, they can be arranged in a valley-like arrangement. Further, the plurality of lead tie bars 21 can be disposed with those approaching the outer edge of the substrate 2 and others departing the same in alternations or may be arranged in staircase-like form.

The electronic components 1 mounted on the substrate 2 are not limited to diodes, transistors, or semiconductor devices constituting a logic, but can be resistors, capacitors, etc.

### Function/Effect of Embodiment

Relative to each conductive pad 2P of the substrate 2, the connecting pieces 11C at the end portions of the bifurcated extension portions 11B of the inner conductor 11 of the lead member 10 come into contact. Therefore, contact in a large area at two portions is made possible. Moreover, with the solder bonding arrangement described above, excess solder will be present in the area surrounding the outer circumferences of the connecting pieces 11C at the two points, thus the contact area of the solder S can be increased, thus realizing increase of the bonding force.

In particular, the pair of connecting pieces 11C of the lead member 10 are set such that an inner end side of the inner conductor 11 will contact under a posture slightly raised from the imaginary plane (from the conductive pad 2P). Therefore, this inner end side will be slightly afloat the conductive pad 2P. When bonding by solder S is effected under this condition, the molten solder S will readily flow from the floating portion into the gap between the connecting piece 11C and the conductive pad 2P, so that the conductive pad 2P and the connecting piece 11C can be firmly bonded to each other over a large area.

Further, the intra-mold conductor area L is bent in a protruding manner relative to the imaginary plane extending along the surface of the substrate 2. Therefore, when an external force is applied to the intra-mold conductor area L in the lead member 10 in association with heat generation in he electronic component package, external forces in opposite directions will be applied from the portion of the first level difference H1 and the portion of the second level difference H2, so that these external forces are cancelled out each other. Consequently, the inconvenience of application of a strong force to the connecting pieces 11C of the inner conductor 11 is suppressed and the connection state between the connecting pieces 11C and the conductive pad 2P can be maintained.

The lead member 10 is configured such that relative the wide portion 11A having the extension portion width W1, the intermediate conductor 12 having the intermediate portion width W2 narrower than the extension portion width W1 extends continuously. Therefore, when an external force is applied in the direction of detaching the lead member 10 from the conductive pad 2P, the wide portion 11A will come into strong contact with the molded portion 3, thereby to strongly prevent displacement in the detaching direction.

The widthwise center of the slit portion 11S and the widthwise center of the intermediate conductor 12 are disposed on the center axis

X. For this reason, like the case described above, when a stress is applied in the direction of detaching the lead member 10 from the conductive pad 2P, inconvenience of strong load being applied to one of the pair of extension portions 11B will be avoided. Namely, loads will be applied equally to the pair of extension portions 11B, so that the contact state of the connecting pieces 11C can be maintained favorably.

Since the intermediate portion width W2 is set larger than the width of the slit portion 11S, even when an external force is applied to these in a twisting direction, displacement thereof in the twisting direction can be suppressed. With this, for instance, even if an external force is applied to the inner conductor 11 of the lead member 10 in the course of setting of the lead frame F to the substrate 2, displacement thereof in the twisting direction can be avoided also.

### Other Embodiments

Alternatively, aside from the embodiment described above, the present invention can be configured as follows also.

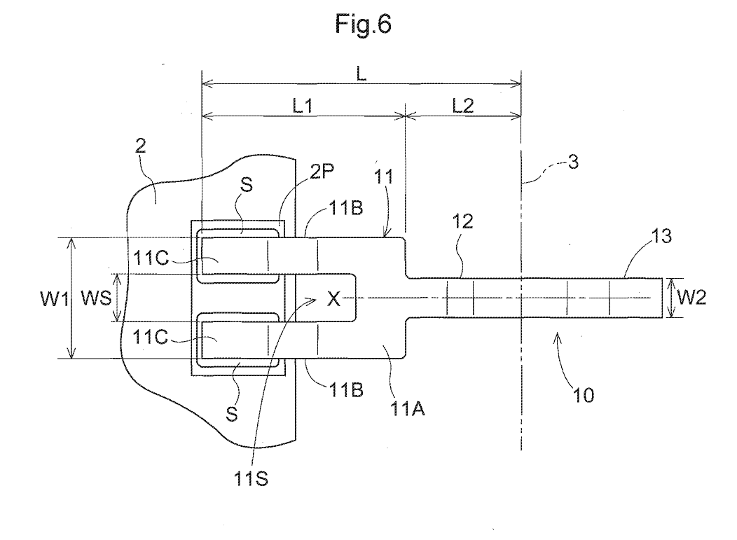

(a) As shown in FIG. 6, in the intra-mold conductor area L, as compared with the extension portion width W1 inclusive of the pair of extension portions 11B (corresponding to the width of the wide portion 11A), the intermediate portion width W2 of the intermediate conductor 12 (a specific example of unitary member) is set smaller and also the intermediate portion width W2 is set smaller than the slit width WS of the slit portion 11S between the pair of extension portions 11B.

With the above-described configuration of this further embodiment (a), when a strong stress is applied to the lead member 10, the pair of extension portions 11B will be readily deformed relative to the intermediate conductor 12. As a result, the phenomenon of strong force being applied in the direction of forcibly detaching the pair of connecting pieces 11C from the conductive pad 2P is suppressed, whereby the contact state of the connecting pieces 11C can be maintained favorably.

(b) The pair of extension portions 11B constituting the inner conductor 11 need not be formed parallel with each other. Instead, the shape of the slit portion 11S can be designed such that the slit becomes wider toward the extension end side (the side of the extension pieces 11C). Conversely, the shape of the slit portion 11S can be designed such that the slit becomes narrower toward the extension end side (the side of the extension pieces 11C).

(c) As the lead member 10, there is employed a conductor having a thickness which is determined by the area extending from the inner conductor 11 to the outer conductor 13. Alternatively, the shape can be varied partially in any desired manner such as forming a rib at the intermediate portion, varying the thickness of a part thereof relative to the rest, etc.

### INDUSTRIAL APPLICABILITY

The present invention can be used in an electronic component package having a lead member conductively connected to a conductive pad of a substrate, with the substrate and a part of the lead member being embedded in a molded portion.

### REFERENCE SIGN LIST

1 electronic component

2 substrate

2P conductive pad

3 molded portion

10 lead member

11 bifurcated end portion (inner conductor)

11C connecting piece

11S slit portion

12 unitary portion (intermediate conductor)

13 unitary portion (outer conductor)

W1 width (extension portion width)

W2 width (intermediate portion width)

WS width (slit width)

X center axis

1. An electronic component package comprising:
a substrate having a conductive pad and mounting an electronic component;
a lead member having bifurcated end portions to be electrically conducted to the conductive pad; and
a molded portion in which the substrate together with the bifurcated end portions and a part of a unitary portion continuous from the bifurcated end portions of the lead portion are embedded therein;
wherein the portions of the lead member embedded in the molded portion are curved in protrusive or sunken manner relative to an imaginary plane extending parallel with a surface of the substrate.

2. The electronic component package according to claim 1, wherein the unitary portion has a width smaller than a width of the bifurcated end portions.

3. The electronic component package according to claim 1, wherein the bifurcated end portions are designed to separate end portions of an inner conductor formed on an inner end side of the lead member from each other with a slit portion therebetween, the slit portion having a greater width than the width of the unitary portion.

4. The electronic component package according to claim 3, wherein a widthwise center of the slit portion and a widthwise center of the unitary portion are disposed on a common center axis.

5. The electronic component package according to claim 3, wherein a pair of contact pieces are formed at inner ends of the inner conductor and set with such a contact angle that causes the pair of contact pieces to contact with a surface of the conductive pad under a posture with inner end side of the pair of contact pieces raised.

6. The electronic component package according to claim 1, wherein:
the lead member includes an inner conductor embedded in the molded portion, an intermediate conductor extending continuously from the inner conductor and embedded in the molded portion, and an outer conductor extending continuously from the intermediate conductor; and
the bifurcated end portions are formed in the inner conductor and the unitary portion is formed in the intermediate conductor and the outer conductor.

7. The electronic component package according to claim 6, wherein:
the inner conductor includes a wide portion and a pair of extension portions extending from the wide portion at positions across a slit portion that separates the end portions of the inner conductor from each other; and
at extension ends of the pair of extension portions, there are formed connecting pieces connected to the conductive pad.

8. The electronic component package according to claim 7, wherein:
in an intra-mold conductor area where the lead member is molded, an area where the inner conductor is present is defined as a first area and an area where the intermediate conductor is present is defined as a second area;
in the first area, a first level difference is set between the contact pieces and a portion of the inner conductor parallel with the imaginary plane; and
in the second area, a second level difference is set between a portion of the intermediate conductor extending continuously from the inner conductor and a portion of the intermediate conductor extending continuously from the outer conductor.

9. The electronic component package according to claim 7, wherein the intermediate conductor has a width which is smaller than a width of the pair of extension portions and which also is greater than the width of the slit portion.

10. The electronic component package according to claim 1, wherein:
a plurality of the lead members are provided to extend along one direction; and
a plurality of lead tie bars for connecting adjacent lead members are arranged in a non-linear manner under a posture perpendicular to the extending direction.
